(19) United States
(12) Patent Application Publication
(10) Pub. No.: US 2021/0088901 A1
(43) Pub. Date: Mar. 25, 2021

(54) PHOTORESIST FOR EUV AND/OR E-BEAM LITHOGRAPHY

(71) Applicant: IMEC VZW, Leuven (BE)

(72) Inventor: Vasiliki Kosma, Leuven (BE)

(21) Appl. No.: 17/020,008

(22) Filed: Sep. 14, 2020

(30) Foreign Application Priority Data
Sep. 20, 2019 (EP) 19198771.8

(51) Int. Cl. G03F 7/004; G03F 7/039; G03F 7/038

(52) U.S. Cl. CPC G03F 7/0045; G03F 7/2004; G03F 7/038; G03F 7/039

(57) ABSTRACT

A photoresist including a photochromic compound suitable for extreme ultraviolet lithography or electron-beam lithography and a structure including the photoresist over a substrate are provided. A method for patterning a substrate is also provided and includes: (a) covering the substrate with the photoresist; (b) exposing the photoresist to an extreme ultraviolet or electron-beam lithographic pattern, the lithographic pattern defining an exposed portion of the photoresist and an unexposed portion of the photoresist, and thereby altering a solubility of the exposed portion towards a developing solvent; and (c) developing a patterned photoresist by contacting the developing solvent with the photoresist.

### CROSS-REFERENCE

This application claims priority from European patent application no. 19198771.8, filed Sep. 20, 2019, which is incorporated by reference in its entirety.

### TECHNICAL FIELD OF THE DISCLOSURE

The present disclosure relates to photoresists and more in particular to photoresists suitable for EUV and/or e-beam lithography.

### BACKGROUND OF THE DISCLOSURE

In view of the continuous quest for scaling down semiconductor devices, extreme ultraviolet (EUV) lithography and electron-beam (e-beam) lithography are being looked to meet pattern requirements needed for advanced technology nodes. In this respect, EUV lithography may be considered to be the most promising candidate for future high-volume manufacturing in the semiconductor industry.

However, the high-power sources and high numerical aperture (NA) used for these lithographic techniques can put stringent requirement on the photoresists used. A major concern at the moment is, for example, whether traditional polymer-based resists—such as chemically amplified resists (CARs)—will be able to satisfy all the criteria for the next generation of EUV patterning.

U.S. Pat. No. 9,454,076B2 discloses a class of molecular glass photoresists comprising bisphenol A as a main structure and their preparation. The molecular glass photoresist is formulated with a photoacid generator, a cross-linking agent, a photoresist solvent, and other additives into a positive or negative photoresist. A photoresist with a uniform thickness is formed on a silicon wafer by spin-coating. The photoresist formulation may be suitable for—inter alia—extreme-ultraviolet (EUV) lithography and electron-beam lithography, and particularly in the EUV-lithography technique.

There is thus still a need in the art to identify better photoresists for use with EUV and e-beam lithography.

### SUMMARY OF THE DISCLOSURE

It is an object of the present disclosure to provide good photoresists for EUV and/or e-beam lithography. It is a further object of the present disclosure to provide good structures, methods and uses associated therewith. This objective is accomplished by photoresists, structures, methods and uses according to the present disclosure.

It is an advantage of embodiments of the present disclosure that the photoresist is suitable for both EUV and e-beam lithography.

It is an advantage of embodiments of the present disclosure that the photoresist comprises few components (e.g. substantially comprising only a single compound).

It is an advantage of embodiments of the present disclosure that the photoresist can be relatively easily applied (e.g. using a solution processing technique). It is a further advantage of embodiments of the present disclosure that a uniform film of the photoresist can be obtained.

It is an advantage of embodiments of the present disclosure that the process from exposure to development of the photoresist requires few steps.

It is an advantage of embodiments of the present disclosure that both positive and negative photoresists can be formulated.

It is an advantage of embodiments of the present disclosure that a relatively small feature size (e.g. 50 nm or less) can be defined and developed into the photoresist.

It is an advantage of embodiments of the present disclosure that they can be performed in a relatively straightforward and economical fashion.

It was realized within the present disclosure that the photoresists commonly used in EUV and/or e-beam lithography are made up of too many individual components, and/or require too many steps for their development. Each component and each step adds a degree of randomness, in turn can lead to more blurred features and more (local) variations and defects in the patterned photoresist. For example, CARs can consist not only of a polymer but also comprise one or more photoactive generators, quenchers, etc. The molecular glass photoresists of U.S. Pat. No. 9,454,076B2 likewise further comprise a photoacid generator and a cross-linking agent. Additionally, both CARs and metal oxide photoresists are typically not ready for development directly after exposure, but may require a further annealing step (e.g. a post-exposure bake) between exposure and development in order to complete their conversion.

Moreover, it was then surprisingly found that photoresists based on photochromic compounds can fill this need. Indeed it was discovered that portions of these photoresists which are exposed to EUV light or to an electron beam directly can undergo a change in solubility (i.e. without relying on additives and without requiring a post-exposure step such as annealing); thereby allowing either the exposed or unexposed portions to be removed selectively with respect to one another and thus develop the exposed photoresist into an patterned photoresist.

In a first aspect, the present disclosure relates to a photoresist for extreme ultraviolet lithography or electron-beam lithography, comprising a photochromic compound.

In a second aspect, the present disclosure relates to a structure comprising the photoresist according to any embodiment of the first aspect over a substrate to be patterned.

In a third aspect, the present disclosure relates to a method for patterning a substrate, comprising: (a) covering the substrate with a photoresist according to any embodiment of the first aspect; (b) exposing the photoresist to an extreme ultraviolet or electron-beam lithographic pattern, the lithographic pattern defining an exposed portion and an unexposed portion of the photoresist, and thereby altering a solubility of the exposed portion towards a developing solvent; and (c) developing the patterned photoresist by contacting the developing solvent with the photoresist.

In a fourth aspect, the present disclosure relates to a use of a photoresist according to any embodiment of the first aspect for extreme ultraviolet lithography or electron-beam lithography.

In a fifth aspect, the present disclosure relates to a use of a mixture comprising a photochromic compound for forming a photoresist according to any embodiment of the first aspect.

Particular aspects of the disclosure are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present disclosure will become apparent from the following detailed description, taken in conjunction with the accompanying drawings, which illustrate, by way of example, the principles of the disclosure. This description is given for the sake of example only, without limiting the scope of the disclosure. The reference FIGURES quoted below refer to the attached drawings.

### BRIEF DESCRIPTION OF THE DRAWINGS

FIG. 1 schematically shows an EUV and e-beam set-up as used in exemplary embodiments of the present disclosure.

### DETAILED DESCRIPTION OF THE DISCLOSURE

The present disclosure will be described with respect to particular embodiments and with reference to certain drawings, but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the disclosure.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms over, under and the like in the description and the claims are used for descriptive purposes and not necessarily for describing relative positions. It is to be understood that the terms so used are interchangeable with their antonyms under appropriate circumstances and that the embodiments of the disclosure described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. Thus, the scope of the expression “a device comprising means A and B” should not be interpreted as being limited to devices consisting only of components A and B. It means that with respect to the present disclosure, the only relevant components of the device are A and B.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the disclosure, various features of the disclosure are sometimes grouped together in a single embodiment, FIGURE, or description thereof for the purpose of streamlining the disclosure and aiding in the understanding of one or more of the various inventive aspects. This method of disclosure, however, is not to be interpreted as reflecting an intention that the claimed disclosure requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

In the description provided herein, numerous specific details are set forth. However, it is understood that embodiments of the disclosure may be practised without these specific details. In other instances, well-known methods, structures and techniques have not been shown in detail in order not to obscure an understanding of this description.

The following terms are provided solely to aid in the understanding of the disclosure.

As used herein, and unless otherwise specified, photochromism is defined as recommended by the International Union of Pure and Applied Chemistry (IUPAC) (see e.g. BRASLAVSKY, Silvia E. Glossary of terms used in photochemistry, (IUPAC Recommendations 2006). Pure and Applied Chemistry, 2007, 79.3: 293-465. or IUPAC. Compendium of Chemical Terminology, 2nd ed. (the “Gold Book”). Compiled by A. D. McNaught and A. Wilkinson. Blackwell Scientific Publications, Oxford (1997). Online version (2019-) created by S. J. Chalk. ISBN 0-9678550-9-8. https://doi.org/10.1351/goldbook.); namely as a reversible transformation of a molecular entity between two forms, A and B, having different absorption spectra, induced in one or both directions by absorption of electromagnetic radiation. A photochromic compound is then a compound which displays photochromism. Such a compound may alternatively be referred to as a ‘photoswitchable chromophore’.

As used herein, and unless otherwise specified, the hydrophilicity of a compound relates to its capacity to interact with polar solvents (e.g. water) or other polar compounds. The hydrophilicity of a compound can typically be quantified using contact angle measurements. For example, if the water contact angle is smaller than 90°, the compound may be considered ‘hydrophilic’; while if the water contact angle is larger than 90°, the compound may be considered ‘hydrophobic’. Likewise, if the water contact angle is lowered, the compound may be said to have become more hydrophilic (and less hydrophobic); while if the water contact angle is increased, the compound may be said to have become more hydrophobic (and less hydrophilic).

In a first aspect, the present disclosure relates to a photoresist for extreme ultraviolet lithography or electron-beam lithography, comprising a photochromic compound.

In embodiments, the photoresist may be with the proviso that the photoresist is substantially free from any additives selected from photoactive generators (e.g. a photoacid generator), cross-linking agents, quenchers, surfactants and sensitizers.

In embodiments, the photoresist may consist of the photochromic compound.

In embodiments, the photochromic compound comprises one or more photochromic moieties selected from azobenzene, stilbene, spiropyran, fulgide and diarylethene. In embodiments, the photochromic compound may be a photochromic compound.

In embodiments, the photochromic compound may have a molecular mass ranging from 300 to 15000 Da. In embodiments, the photochromic compound may be an n-mer, where n ranges from 1 to 50. The photochromic compound may thus be a monomer, dimer, trimer, oligomer or polymer. Smaller photochromic compounds (i.e. having a molecular mass closer to 300 Da) may be desirable in view of ensuring a good pattern feature resolution. Indeed, since the material will in those cases be more finely grained (e.g. as opposed to longer polymer chains), the boundary between exposed and unexposed portions of the photoresist (cf. infra) can be more tightly defined. Conversely, larger photochromic compounds (i.e. having a molecular mass of 6000 Da and higher) may more easily allow to deposit uniform films thereof and may be desirable for that reason. A trade-off between both qualities can typically be found for intermediately sized compounds (e.g. having a molecular mass ranging from 1500 to 4500° Da; such as oligomers or short polymers).

In embodiments, the photochromic compound may be a polymer having pendant groups comprising one or more photochromic moieties selected from azobenzene, stilbene, spiropyran, fulgide and diarylethene; usually an azobenzene or stilbene moiety.

In embodiments, the polymer may be selected from a poly(Disperse Red 1 methacrylate), a poly[1-[4-(3-carboxy-4-hydroxyphenylazo)benzenesulfonamido]-1,2-ethanediyl], or a poly(N-acryloylphenylalanine benzyl-ester-co-acryloyloxyethyl-dimethylamino) quaternized with 4-chloromethylphenylcarbamoyloxymethylstilbene. Disperse Red 1 is an azo-dye with systematic name N-Ethyl-N-(2-hydroxyethyl)-4-(4-nitrophenylazo)aniline. Poly(Disperse Red 1 methacrylate) is commercially available from Sigma-Aldrich. A sodium salt of poly[1-[4-(3-carboxy-4-hydroxyphenylazo)benzenesulfonamido]-1,2-ethanediyl], PAZO, is also commercially available from Sigma-Aldrich; however, it is generally useful to avoid metals such as sodium in semiconductor processing because they can lead to unwanted contaminations. The carboxylic acid form or another suitable salt (e.g. an ammonium salt) can however be relatively straightforwardly synthesized; either directly or obtained from PAZO (e.g. through an ion-exchange reaction). The poly(N-acryloylphenylalanine benzyl-ester-co-acryloyloxyethyl-dimethylamino) quaternized with 4-chloromethylphenylcarbamoyloxymethylstilbene may be as disclosed by Buruiana et al. and may be synthesized as described therein (BURUIANA, Emil C., et al. Photo-polymers containing (S)-phenylalanine and stilbene pendants: synthesis and properties of ionic polyacrylates. Designed Monomers and Polymers, 2010, 13.1: 21-32.)

In embodiments, the photoresist may be a layer comprising (or consisting of) the photochromic compound. In embodiments, the layer may cover a substrate to be patterned (cf. the second aspect). In embodiments, the layer may be a uniform layer. In embodiments, the layer may be a patterned layer. The patterned layer may for example comprise regions comprising the photochromic compound (e.g. with a substantially thickness) and patterned openings between said regions.

In embodiments, any feature of any embodiment of the first aspect may independently be as correspondingly described for any embodiment of any of the other aspects.

In a second aspect, the present disclosure relates to a structure comprising the photoresist according to any embodiment of the first aspect over a substrate to be patterned.

The nature of the substrate to be patterned is not typically crucial, as long as the photoresist can be applied thereon. Any substrate commonly used in semiconductor processing can thus generally be suitable. In particular embodiments, the substrate to be patterned may be a Si wafer.

In embodiments, any feature of any embodiment of the second aspect may independently be as correspondingly described for any embodiment of any of the other aspects.

In a third aspect, the present disclosure relates to a method for patterning a substrate, comprising: (a) covering the substrate with a photoresist according to any embodiment of the first aspect; (b) exposing the photoresist to an extreme ultraviolet or electron-beam lithographic pattern, the lithographic pattern defining an exposed portion and an unexposed portion of the photoresist, and thereby altering a solubility of the exposed portion towards a developing solvent; and (c) developing the patterned photoresist by contacting the developing solvent with the photoresist.

In embodiments, covering the substrate may comprise coating the substrate. In embodiments, coating the substrate may comprise a solution processing technique. In embodiments, the solution processing technique may be selected from spin coating, dip coating, doctor blade, slot coating and spray coating; usually spin coating. In embodiments, step a may comprise coating the substrate from a mixture comprising the photochromic compound. In embodiments, the mixture comprising the photochromic compound may comprise—e.g. consist of—the photochromic compound dispersed in a solvent. In embodiments, the mixture may comprise 0.5 to 5 wt % of the photochromic compound, such as 1 to 2 wt %. In embodiments, the solvent may be a polar or non-polar solvent. The selection of the solvent may typically depend on the nature of the photochromic compound.

In embodiments wherein step b comprises exposing the photoresist to the extreme ultraviolet lithography, defining the exposed portion and the unexposed portion of the photoresist may be by exposing the photoresist to a pattern of EUV light. In embodiments, the pattern of EUV light may be obtained by reflecting EUV light off an EUV reticle (i.e. an EUV mirror covered with a patterned absorber; may be alternatively referred to as an ‘EUV mask’).

In embodiments wherein step b comprises exposing the photoresist to the electron-beam lithography, defining the exposed portion and the unexposed portion of the photoresist may be by exposing the photoresist to a pattern of electrons. In embodiments, the pattern of electrons may be obtained by writing the pattern onto the photoresist using an electron beam.

In embodiment, altering the solubility of the exposed portion towards the developing solvent may be with respect to the unexposed portion. The exposure thus can beneficially result in a change in solubility between the exposed and the unexposed portion, which is then leveraged in step c. Without being bound by theory, the change in solubility may be due to a change in hydrophilicity in the exposed portion. Upon exposure, the photochromic compound may, for example, undergo a reaction resulting in a more hydrophobic (or more hydrophilic) reaction product. In embodiments, exposing the photoresist in step b may directly result in the alteration of the solubility. In embodiments, step c may be performed directly after step b; i.e. without an intermediate step therebetween (e.g. a post-exposure annealing step, such as a post-exposure bake).

In embodiments, step c may comprise dissolving the exposed portion of the photoresist, or may comprise dissolving the unexposed portion of the photoresist. In embodiments, the exposed portion may be dissolved selectively with respect to the unexposed portion; or vice versa. Depending on which portion is removed, the photoresist may thus advantageously be used as either a positive or negative tone photoresist, respectively.

In embodiments, the lithographic pattern may comprise a feature having a size of 70 nm or less, 50 nm or less, or 30 nm or less. In embodiments, the lithographic pattern may have a minimum feature size (alternatively referred to as ‘critical dimension’) of 70 nm or less, 50 nm or less, or 30 nm or less. In embodiments, the developed photoresist may comprise a feature having a size of 70 nm or less, 50 nm or less, or 30 nm or less. In embodiments, the developed photoresist may have a minimum feature size of 70 nm or less, 50 nm or less, or 30 nm or less.

In embodiments, the developing solution (alternatively referred to as ‘developer’) may be a solvent. In embodiments, the developing solution may be a polar or non-polar solution (e.g. a polar or non-polar solvent). In embodiments, the developing solution may comprise (e.g. consist of) the solvent used to deposit the photoresist.

In embodiments, any feature of any embodiment of the third aspect may independently be as correspondingly described for any embodiment of any of the other aspects.

In a fourth aspect, the present disclosure relates to a use of a photoresist according to any embodiment of the first aspect for extreme ultraviolet lithography or electron-beam lithography. The photoresist may for example be used as in steps b and c of the third aspect.

In embodiments, any feature of any embodiment of the fourth aspect may independently be as correspondingly described for any embodiment of any of the other aspects.

In a fifth aspect, the present disclosure relates to a use of a mixture comprising a photochromic compound for forming a photoresist according to any embodiment of the first aspect. The mixture may for example be used as in step a of the third aspect.

In embodiments, any feature of any embodiment of the fifth aspect may independently be as correspondingly described for any embodiment of any of the other aspects.

The disclosure will now be described by a detailed description of several embodiments of the disclosure. It is clear that other embodiments of the disclosure can be configured according to the knowledge of the person skilled in the art without departing from the true technical teaching of the disclosure, the disclosure being limited only by the terms of the appended claims.

### Example 1

20 mg of poly(Disperse Red 1 methacrylate)—obtained from Sigma Aldrich—with chemical formula

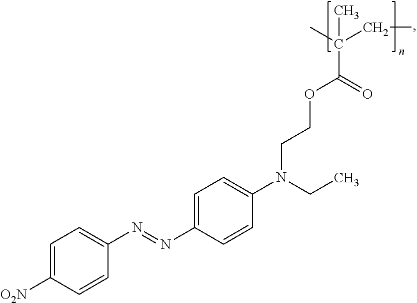

was dissolved in THF to form a 0.5 wt % solution. The solution was filtrated and spin coated on a Si wafer to provide a uniform photoresist film, which was subsequently exposed under static EUV light for about 20 s (corresponding to a flux density of about 100 mJ/cm²).

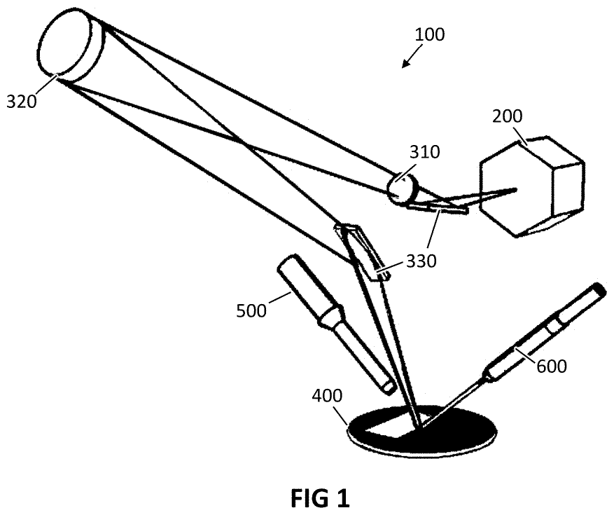

The set-up (100) used, schematically shown in FIG. 1, exposed a 200 mm resist-coated substrate (400) either by EUV photons or by electrons. For the EUV exposure, an Energetiq EQ-10 source (200) was integrated in the tool, supplying 10 W/2πsr EUV irradiation into the system. This light was filtered by a Zr spectral purity filter (SPF, 310) and reflected by a multilayer (ML) mirror (320; i.e. the EUV reticle) and grazing incidence mirrors (330) towards the substrate (400). Spot size on the wafer was 10 mm² and the power density was about 4 mW/cm² with a wavelength of 13.5 nm. The tool enables also electron exposure by electron gun (600) on the resist (see e.g. example 4) and an outgas tool (500) with a Pfeiffer QMG422 mass spectrometer, which measures over a broad atomic mass unit (amu) range of 1 to 512 amu.

As developer, mixtures of water and THF with respective ratios from 1:1 to 1:3 were used. Under these circumstances, the developer dissolved the exposed portions of the photoresist (i.e. those portions previously exposed to EUV) to yield a positive tone resist.

### Example 2

A 2 wt % solution in water of a poly[1-[4-(3-carboxy-4-hydroxyphenylazo)-benzenesulfonamido]-1,2-ethanediyl], with chemical formula

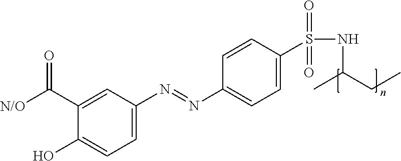

where M is a monovalent cation (e.g. H⁺), was made. After filtration and spin coating on a Si wafer, a uniform photoresist film was obtained and subsequently exposed under static EUV light with a flux density of about 70 mJ/cm² using the same EUV set-up as in example 1. Using water as developer, the unexposed portions of the photoresist (i.e. those portions previously not exposed to EUV) were dissolved to yield a negative tone resist.

### Example 3

A 2 wt % solution in DMSO of a poly(N-acryloylphenylalanine benzyl-ester-co-acryloyloxyethyl-dimethylamino) quaternized with 4-chloromethylphenylcarbamoyloxymethylstilbene, with chemical formula

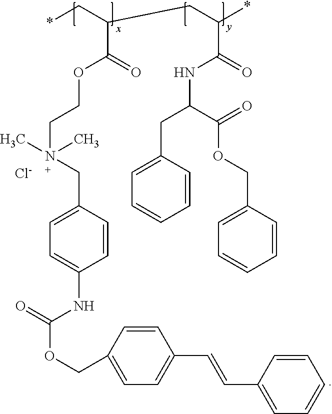

is made. After filtration and spin coating on a Si wafer, a uniform photoresist film is obtained and subsequently exposed under EUV light using the same EUV set-up as in example 1. Using DMSO as developer, the unexposed portions of the photoresist (i.e. those portions previously not exposed to EUV) were dissolved to yield a negative tone resist.

### Example 4

Examples 1 to 3 are repeated but using e-beam lithography instead of EUV lithography.

It is to be understood that although various embodiments, specific constructions and configurations, as well as materials, have been discussed herein for devices according to the present disclosure, various changes or modifications in form and detail may be made without departing from the scope and technical teachings of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

1. A photoresist for extreme ultraviolet lithography or electron-beam lithography, comprising a photochromic compound.

2. The photoresist according to claim 1, with the proviso that the photoresist is substantially free from any additives selected from photoactive generators, cross-linking agents, quenchers, surfactants and sensitizers.

3. The photoresist according to claim 1, consisting of the photochromic compound.

4. The photoresist according to claim 1, wherein the photochromic compound comprises one or more photochromic moieties selected from azobenzene, stilbene, spiropyran, fulgide and diarylethene.

5. The photoresist according to claim 1, wherein the photochromic compound has a molecular mass ranging from 300 to 15000 Da.

6. The photoresist according to claim 1, wherein the photochromic compound is a polymer having pendant groups comprising an azobenzene or stilbene moiety.

7. The photoresist according to claim 6, wherein the polymer is selected from a poly(Disperse Red 1 methacrylate), a poly[1-[4-(3-carboxy-4-hydroxyphenylazo)-benzenesulfonamido]-1,2-ethanediyl], and a poly(N-acryloyl-phenylalanine benzyl-ester-co-acryloyloxyethyl-dimethylamino) quaternized with 4-chloromethylphenylcarbamoyloxymethylstilbene.

8. A structure comprising the photoresist according to claim 1 over a substrate to be patterned.

9. A method for patterning a substrate, comprising:
a) covering the substrate with a photoresist as defined in claim 1;
b) exposing the photoresist to an extreme ultraviolet or electron-beam lithographic pattern, the lithographic pattern defining an exposed portion of the photoresist and an unexposed portion of the photoresist, and thereby altering a solubility of the exposed portion towards a developing solvent; and
c) developing a patterned photoresist by contacting the developing solvent with the photoresist.

10. The method according to claim 9, wherein step a comprises coating the substrate with a mixture comprising a photochromic compound.

11. The method according to claim 10, wherein the mixture comprising the photochromic compound consists of the photochromic compound dispersed in a solvent.

12. The method according to claim 9, wherein the lithographic pattern comprises a feature having a size of 50 nm or less.

13. The method according to claim 9, wherein step c comprises dissolving the exposed portion of the photoresist, or comprises dissolving the unexposed portion of the photoresist.

14. The method according to claim 9, with the proviso that the photoresist is substantially free from any additives selected from photoactive generators, cross-linking agents, quenchers, surfactants and sensitizers.

15. The method according to claim 9, wherein the photoresist consists of the photochromic compound.

16. The method according to claim 9, wherein the photochromic compound comprises one or more photochromic moieties selected from azobenzene, stilbene, spiropyran, fulgide and diarylethene.

17. The method according to claim 9, wherein the photochromic compound has a molecular mass ranging from 300 to 15000 Da.

18. The method according to claim 9, wherein the photochromic compound is a polymer having pendant groups comprising an azobenzene or stilbene moiety.

19. The method according to claim 18, wherein the polymer is selected from a poly(Disperse Red 1 methacrylate), a poly[1-[4-(3-carboxy-4-hydroxyphenylazo)-benzenesulfonamido]-1,2-ethanediyl], and a poly(N-acryloyl-phenyl-alanine benzyl-ester-co-acryloyloxyethyl-dimethylamino) quaternized with 4-chloromethylphenylcarbamoyloxymethylstilbene.
